(19) United States
(12) Patent Application Publication
(10) Pub. No.: US 2004/0250769 A1
(43) Pub. Date: Dec. 16, 2004

(54) Pulsed laser deposition for mass production

(75) Inventors: William Freeman, Castro Valley, CA (US); Ming K. Shi, Pleasanton, CA (US)

Correspondence Address: WORKMAN NYDEGGER (F/K/A WORKMAN NYDEGGER & SEELEY), 60 EAST SOUTH TEMPLE, 1000 EAGLE GATE TOWER, SALT LAKE CITY, UT, 84111, US

(73) Assignee: Finisar Corporation

(21) Appl. No.: 10/757,032

(22) Filed: Jan. 13, 2004

Related U.S. Application Data
(63) Continuation-in-part of application No. 10/695,384, filed on Oct. 28, 2003, now abandoned.
(60) Provisional application No. 60/421,885, filed on Oct. 28, 2002.

(51) Int. Cl. C23C 16/00

(52) U.S. Cl. 118/718; 118/722

(57) ABSTRACT

A unique system and method for laser vapor deposition of a material onto a substrate are disclosed. The system includes a laser source configured to emit a laser beam, a target material positioned in front of the laser source to be struck by the laser beam, and a substrate positioned behind the target material in relation to the laser beam. The laser beam strikes the target material causing a portion thereof to melt. The melting zone propagates through the target material until is reaches the opposing surface, and a vaporized portion of the target material is ejected onto the substrate. The target material can be deposited onto the substrate in a pre-determined pattern with a pre-determined thickness. In another embodiment of the invention, the target material can be deposited on a cassette structure to facilitate easy access.

### CLAIM TO PRIORITY

This application is a continuation-in-part patent application of U.S. patent application Ser. No. 10/695,384, filed Oct. 28, 2003, entitled “Pulsed Laser Deposition for Mass Production”, which claims priority to and the benefit of U.S. Provisional Patent Application No. 60/421,885, filed on Oct. 28, 2002, entitled, “Pulsed Laser Deposition for Mass Production”, which are incorporated herein by reference in its entirety.

### BACKGROUND OF THE INVENTION

2. The Field of the Invention

This invention relates generally to the field of vapor deposition of a material onto a substrate. In particular, embodiments of the present invention relate to an improved method of pulsed laser deposition of a material onto a substrate.

3. The Relevant Technology

To form various optical components it is sometimes necessary to deposit a material upon the optical components. For instance, some lenses or prisms can be coated with one or more layers to enable to lens or prism to change a polarization of a beam passing therethrough or filtering one or more wavelengths of electromagnetic radiation. Other times it can be necessary to deposit a metallic layer upon a substrate, such as for plating. One of the most common optical applications is the creation of anti-reflection (AR) coatings on all the optical surfaces where an abrupt change in refractive index occurs.

Currently, to deposit a seed layer upon a substrate in a desired pattern, for instance during plating, it is necessary to cover the whole surface of the substrate with a thin layer of the seed metal. Once the substrate is covered, a photoresist is applied to the thin layer and patterned to achieve the desired mask. Portions of the resist are stripped and the exposed seed metal is removed during an etching process. Unfortunately, this process requires a complicated system to achieve the deposition and etching.

Illustrated in FIG. 1 is one example of a pulsed laser deposition (PLD) process, designated generally at 100. The process 100 uses a pulsed laser source 30, such as an ultraviolet (UV) semiconductor laser, to direct a beam 36 of energy toward a target 20. The laser source 30 is selectively turned “on” and “off” by attached external circuitry (not shown) or can be modulated to create the necessary pulsed laser beam, as is known to those skilled in the art.

The pulsed laser source 30 intermittently transmits beam 36 to target 20 that is made from the material to be deposited upon substrate 10 to give substrate 10 specific optical or electrical properties. The beam 36 strikes target 20 at a specific location, resulting in the material forming target 20 to rapidly heat up. The pulse duration, wavelength, and the laser beam intensity are designed to only penetrate a certain depth of target 20, typically no more than about 1000Å, depending on the type and thickness of material used as target 20.

The pulse duration and beam intensity cause rapid heating of target 20 and cause a portion of target 20 to rapidly change from a solid material to a gas, termed sublimation. The vaporized target material forms a plume 40, which is ejected away from target 20 and toward substrate 10 at a very rapid velocity, typically supersonic. The target 20 and substrate 10 are positioned so that plume 40 will naturally move toward substrate 10. Depending upon the temperature and wavelength, thus whether there is a serious amount of ionization or not, the plume is mostly a plasma, meaning that the electrons and nuclei are largely separated or at least most of the atoms are highly ionized. This plume is capable of embedding itself through melting and diffusion into the substrate.

Currently, laser deposition occurs in a vacuum to ensure that atmospheric pressure has no affect on the movement of plume 40. As plume 40 settles onto substrate 10, the material in the plume is cooled by the surface temperature of substrate 10 and solidifies into a thin film on top of substrate 10. Numerous layers of deposited target material can be deposited upon all or a portion of substrate 10 to create the desired pattern on substrate 10. Multiple pulses from laser 30 can be used to produce a film of a desired thickness. It is possible, using PLD, to deposit a film on a substrate that is anywhere from 1.2 nanometers to 200 nanometers or more in thickness. With the tradeoff between adhesion and film stress, depositing films having other thicknesses is possible.

One problem with conventional PLD, such as that illustrated in FIG. 1, is that it wastes a significant amount of material, because much of the vaporized target material dissipates away from substrate 10 and is not deposited thereon. Another problem with conventional PLD is that conducting the process in a vacuum increases the costs associated with equipment, preparation, and production of thin films on a substrate.

### SUMMARY OF THE INVENTION

In order to overcome these and other problems inherent in the art, unique systems and methods for laser vapor deposition of a material onto a substrate are disclosed. The system includes a laser source configured to emit a laser beam, a target material positioned in front of the laser source so as to be struck by the laser beam, and a substrate positioned behind the target material in relation to the laser beam. The laser beam strikes the target material causing a portion thereof to melt. The melting zone propagates through the target material until is reaches the surface, and a vaporized portion of the target material is ejected onto the substrate. The target material can be deposited onto the substrate in a pre-determined pattern with a pre-determined thickness. This technique is usually referred to as forward ablation. When the substrate is transparent to the wavelength of the laser light then a technique of backward ablation may be used. In backward ablation, the laser beam is directed through the substrate onto the target and the plume expands backwards towards the side adjacent to the target and farthest from the laser. The plume used in backward ablation is more particle free than for the plume associated with forward ablation. Additionally, the technique of backward ablation can be used with various target material thicknesses.

The system can further include a cassette to more precisely hold the target material. The cassette can include a web that has the target material deposited thereon, a pair of reels connected to either end of the web for receiving and delivering the web, and a housing supporting the flexible web and the pair of reels.

The method for depositing a target material onto a substrate can include the step of directing a laser beam at a target where the target has a web having one or plural target materials in different sections. The substrate is positioned in close proximity to the distal side of the target material. The first step is to direct the laser beam to the first target material so as to transmit a vaporized portion of the target material onto the substrate. The next step is to move the target material over the laser beam to deposit the second material on the substrate. The process can be repeated and many different materials can be deposited on the same substrate. When simultaneous deposition of multiple materials, possibly for the purpose of alloying, from several different targets then the vacuum chamber approach is desirable. However, usually this is not necessary because the desired composition can be produced on a single tape and can then be ablated simultaneously. When reactive mixtures and certain unstable alloys are to be deposited, it is desirable to use a vacuum chamber approach to depositing the materials.

These and other objects and features of the present invention will become more fully apparent from the following description and appended claims, or can be learned by the practice of the invention as set forth hereinafter.

### BRIEF DESCRIPTION OF THE DRAWINGS

In order that the manner in which the above-recited and other advantages and features of the invention are obtained, a more particular description of the invention briefly described above will be rendered by reference to specific embodiments thereof that are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1 illustrates a pulsed laser deposition process.

FIG. 2 illustrates a generalized pulsed laser deposition process.

FIG. 3 illustrates a schematic representation of a laser beam being incident upon a target material of the process of FIG. 2;

FIG. 4 illustrates a schematic representation of another laser beam being incident upon another target material of the process of FIG. 2;

FIG. 5 is a perspective view of a cassette containing target material for use with the pulsed laser deposition process of FIG. 2;

FIGS. 6A and 6B is a schematic representation of a cross-sectional side view of a web of the cassette of FIG. 5; and

FIG. 7 depicts another embodiment of a system usable in a pulsed laser deposition process incorporating the cassette of FIG. 5.

### DETAILED DESCRIPTION OF THE EXEMPLARY EMBODIMENTS

In general, the present invention relates to an improved process for pulsed laser deposition (PLD). The improved process positions the target material and the substrate in close proximity to one another to increase the deposition precision and minimize the amount of wasted material. This improved process is less affected by atmospheric pressure than current techniques. The improved process may be practiced outside of a vacuum or reduced pressure vessel.

While exemplary processes are described in the context of optical thin film depositions, it will be appreciated that the exemplary process may be used to deposit other materials. For instance, this technique has applicability for rapid prototyping and manufacturing of various electronic thin film coatings. In particular, the technique can be used for applications where the percentage of the surface that needs to be coated is low. Consequently, this technique can be very efficient in terms of time, material, and energy.

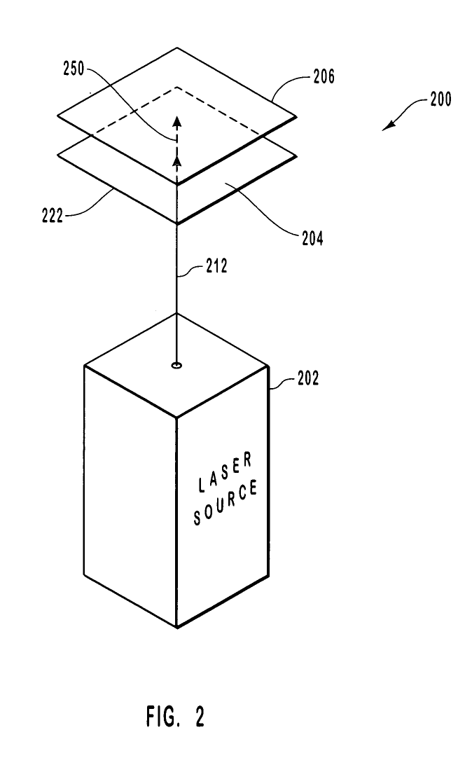

FIGS. 2-7 describe exemplary embodiments of the present invention. The figures are diagrammatic and schematic representations of the exemplary embodiments, and are not limiting of the present invention, nor are they necessarily drawn to scale.

FIG. 2 illustrates a system useable for performing an improved PLD process in accordance with one aspect of the present invention; numeral 200 designates the system. The process utilizing system 200 improves on the standard PLD process in that it more precisely deposits the target material onto a substrate and minimizes the amount of target material wasted during the process. The system 200 includes a laser source 202 that emits a pulsed laser beam 212, a selectively vaporized target 204, and a substrate 206 that receives the vaporized material and is at least partially transparent to laser beam 212.

The improved process of the present invention need not be conducted in a vacuum because of the close proximity between target 204 and substrate 206. The process can, however, be performed in a vacuum. In such a case, the level of vacuum need is many times lesser than the vacuums for standard PLD process. For instance, the vacuum used for the present invention can be between about 10⁻¹ mtorr and about 10⁻² mtorr. Similarly, the size of vacuum chamber needed is many times smaller than is needed for standard PLD processes. It will be understood that the present invention can also be practiced used existing vacuums and vacuum chambers.

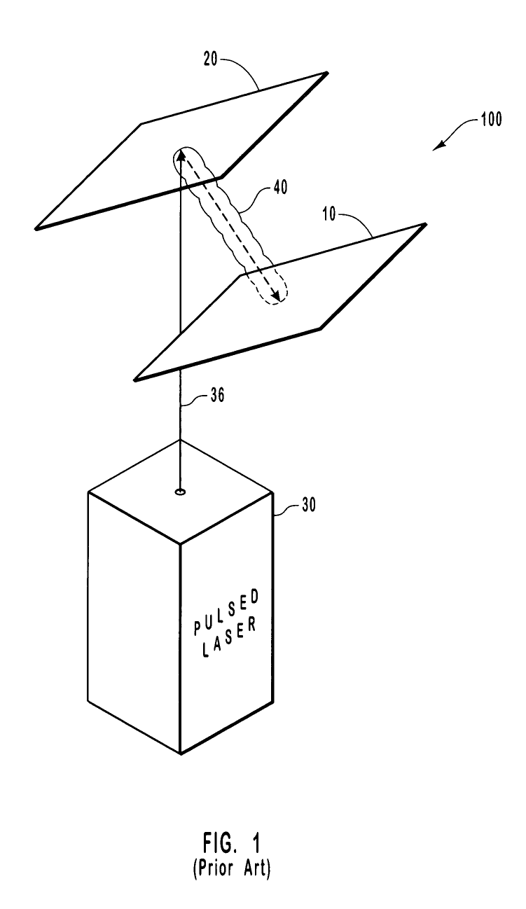

One of the principal differences between the improved process and the conventional process is that, according to the invention, target 204 and substrate 206 are aligned vertically in relation to laser source 202. Otherwise, laser source 202, target 204 and substrate 206 can be similar in structure to the corresponding components of the conventional process described with reference to FIG. 1. Another difference between the improved process and the conventional PLD process is that substrate 206 is disposed in close proximity to or in contact with target 204. For instance, the distance between substrate 206 and target 204 can be between about 0 microns to about 100 microns.

In operation of system 200, activating laser source 202 initiates the improved process. Laser source 202 can intermittently emit an ultraviolet (UV) laser beam 212 that is incident upon target 204. Although reference is made to a UV laser beam generated by laser source 202, one skilled in the art will appreciate that laser source 202 can generate beams

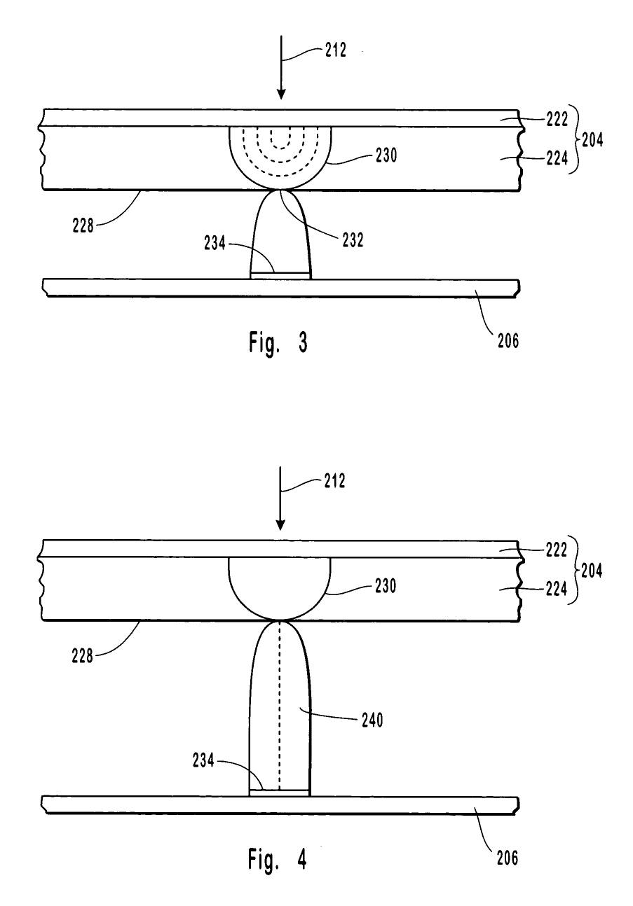

The laser beam 212 emitted from laser source 202 strikes target 204 at a precise location on surface 222 of target 204. The target 204 includes a web 222 with a target material 224 coated thereupon, as illustrated in FIG. 3. The web 222 can be at least partially transparent to the electromagnetic radiation of beam 212. The web 222 can have a uniform solid structure, matrix structure, mesh structure, combinations thereof, or other structure that supports target material 224. The web 222 can be fabricated from metals, synthetic materials, natural materials, plastics, polymers, combinations thereof, or other materials that provide sufficient structural support to transport material 224.

The target material 224 deposited upon web 222 can be any material that can be deposited upon substrate 206. For instance, target material 224 can include metals, alloys, and materials having valence electrons in the d-orbital, materials having valence electrons in the f-orbital, alkaline earths, or any other materials to generate desired gaseous regions about beam 212, substrate 206, and/or target 204.

The laser beam 212 penetrates target to a specific depth based upon the pulse duration, wavelength, and intensity of laser beam 212. The laser beam 212 is incident upon target material 224. As laser beam 212 heats target material 224, heat diffuses through target material 224 creating a melting zone 230 in target material 224. This melting zone 230 propagates through target material 224 until it reaches surface 228. Upon reaching surface 228, a vapor pressure created by melting target 204 causes ejection of target material 224 from an aperture 232 created from the melting process onto substrate 206; such deposited target material being identified by reference numeral 234. A diameter of the ejected target material 224 is smaller than the diameter of laser beam 212. Further, the close spacing of target material 224 to substrate 206 prevents the vaporized target material 224 from developing into a plume and makes the deposition of the target material 224 onto substrate 206 more precise. As with other configurations, deposited target material 224 cools to form the desired thin film layer of target material.

Laser beam 212 directs energy to a specific location of target 204 to cause deposition of target material 224 upon a specific location of substrate 206. In this manner, the present invention limits the amount of target material 224 needed to form the desired layer or coating upon substrate 206. A reduction in the costs associated with depositing target material 224 compared with existing techniques results. For instance, when covering a small area of substrate 206 with target material 224 the present invention can deposit target material 224 directly upon that location. In contrast, existing techniques require masking of the specified location, depositing of target material over the entire substrate, and subsequent removal of the mask or photoresist material. This is time consuming and expensive.

In another configuration of the present invention, as illustrated in FIG. 4, substrate 206 and target 204 are separated to a greater degree than with the embodiment described with respect to FIG. 3. The aspects of the embodiment described with respect to FIG. 3 are applicable to the discussion of the embodiment depicted in FIG. 4, and vice versa. Substrate 206 is about 1 mm from target 204. Although separation of substrate 206 and target 204 is about 1 mm, one skilled in the art can appreciate that the separation can be between about 1 mm and about 30 cm. In other configurations, separation of substrate 206 and target 204 is about less than 1 mm, such as, but not limited to, a few microns, 10's of microns, a couple of hundred microns, between about 1 micron and 300 microns, or some other desirable separation known to those skilled in the art in light of the teaching contained herein. As the separation between target and substrate increases it may be desirable to remove the atmosphere. Additionally, special effects are desired from the deposited coating it may be desirable to deposit the materials within a special atmosphere.

With the configuration of FIG. 4, upon melting zone 230 reaching surface 228, a vapor pressure created by melting target 204 causes target material 224 to eject from an aperture 232. Due to the increased distance between target 204 and substrate 206, a plume 240 of ablated target material 224 forms. This plume 240 extends from target 204 to substrate 206, thereby depositing vaporized target material 224. With this configuration, the quantity of target material deposited upon substrate 206 is the same, but the area covered is greater than for the configuration of FIG. 3 because plume 240 expands as it traverses the distance between target 204 and substrate 206 so the deposited film is correspondingly thinner. As with other configurations, the deposited target material 224 cools to form the desired thin film layer of target material. This cooling may be desirable, but if not then the substrate can be heated to compensate for decreases in temperature.

When the process of ablation is performed within a vacuum chamber, using a technique of ion assist compensates for decreases in the temperature of target material 224. The ion assist technique effectively maintains the surface at a very high equivalent temperature without significantly heating the bulk of the substrate. This can be very useful for promoting nucleation of mono-crystalline films.

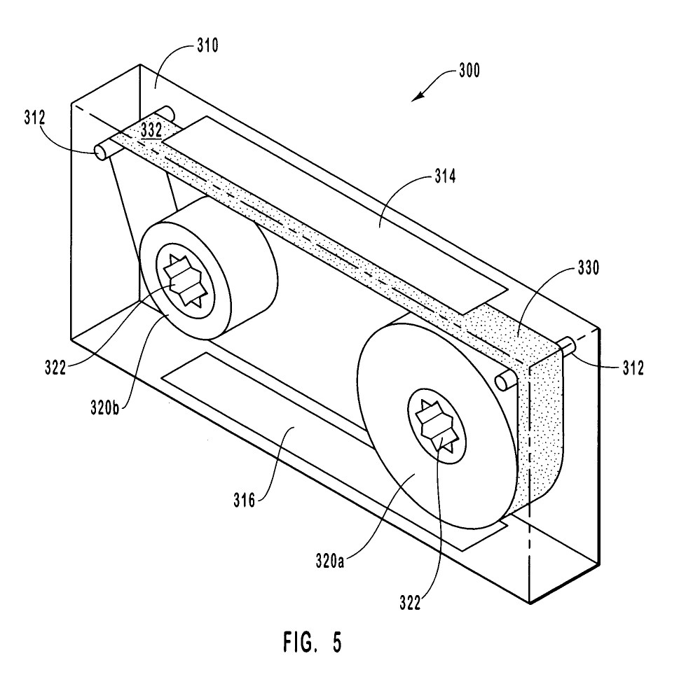

FIG. 5 illustrates a perspective view of a cassette-type structure containing target material for use with the improved PLD system and process described with respect to FIG. 2. The cassette 300 facilitates easy transitioning between different target materials in the improved PLD process and system. Using a cassette containing different target material located in different section, deposition of one or plural target material onto one or different substrates can be realized. Following substitution of the first material, the web containing the second target material can be moved over the laser beam to deposit a second target material on the substrate. By repeating the same process, different target material can be deposited on the same substrate. One skilled in the art will understand that any number of cassettes containing different target material can be used to achieve desired results for the particular substrate. For instance, cassettes containing different materials can be substituted for one another to provide different target materials.

As illustrated, cassette 300 has a housing 310 within which are disposed a pair of reels 320a and 320b that support a flexible web 330 containing a target material 332. Housing 310 includes upper window 314 and a lower window 316. These windows 314 and 316 provide a path for laser beam 212 (FIG. 2) to pass during the PLD process. The lower window 316 enables laser beam 212 (FIG. 2) to strike a bottom portion of web 330 without attenuation or loss of laser power in the PLD process. Lower window 316 can include a material transparent to the wavelength of electromagnetic radiation directed to web 330 or can simply be a gap in housing 310. The upper window 314 is a gap in housing 310 so that target material 332 contained on an upper portion of web 330 can be deposited onto a substrate (not shown) without interference in the PLD process. Each window 314 and 316 can extend partially or completely along the length of cassette 300. In other configurations, the cassette includes one or more upper and lower windows to accommodate one or more laser beams.

As mentioned above, reels 320a and 320b rotatably mount within housing 310. Rotatably mounting reels 320a and 320b within housing 310 allows transfer of web 330 between reels, such as from reel 320a to 320b. With web 330 attached to both reels 320a and 320b, when one portion of target material 332 is completely ablated from web 330 in a PLD process, reels 320a and 320b allow a user or a machine (not shown) to advance web 330 to provide a fresh section of target material 332 to be deposited. This ensures consistent exposure of a portion of web 330 having target material to a laser beam from a radiation source, such as radiation source 202 (FIG. 2).

Each reel 320a and 320b includes a recess 322 that receives a portion of a device or machine (not shown) that facilitates rotation of reels 320a and 320b to transfer web 330 as described herein. Recess 322 can have various configurations so long as it drivingly engages with the device or machine (not shown) for moving reels 320a and 320b.

To aid in positioning and/or moving web 330, housing 310 includes one or more guides 312 located at various positions on an interior and/or exterior of housing 310. Each guide 312 can be either fixed or movable depending upon the desired function. For instance, one or more of guides 312 can aid with maintaining a tension in web 330 as it travels between reels 320a and 320b. This tension limits the possibility of web 330 becoming unwound from reels 320a and 320b or damaged during movement of reels 320a and 320b. This tension is created as a biasing force is applied to web 330 when reels 320a and 320b are prevented from moving by the device or machine (not shown) that rotates one or both of reels 320a and 320b. Alternatively, disposing one or more biasing members, such as springs, leaf-type springs, or resilient members, in contact with an intermediate portion of web 330, such as close to an upper window 314, creates the desired tension upon web 330.

The web 330 is a tape or other flexible material that receives a desired target material 332. Generally, web 330 can have a relatively high melting point so as not to melt and contaminate target material 332 in the PLD process. Alternatively, web 330 can be at least partially transparent to the wavelength of electromagnetic radiation generated by laser source 202 (FIG. 2). For example, web 330 can have a similar configuration to web 230 (FIG. 2), such as, but not limited to, a mesh, matrix, or solid piece of material.

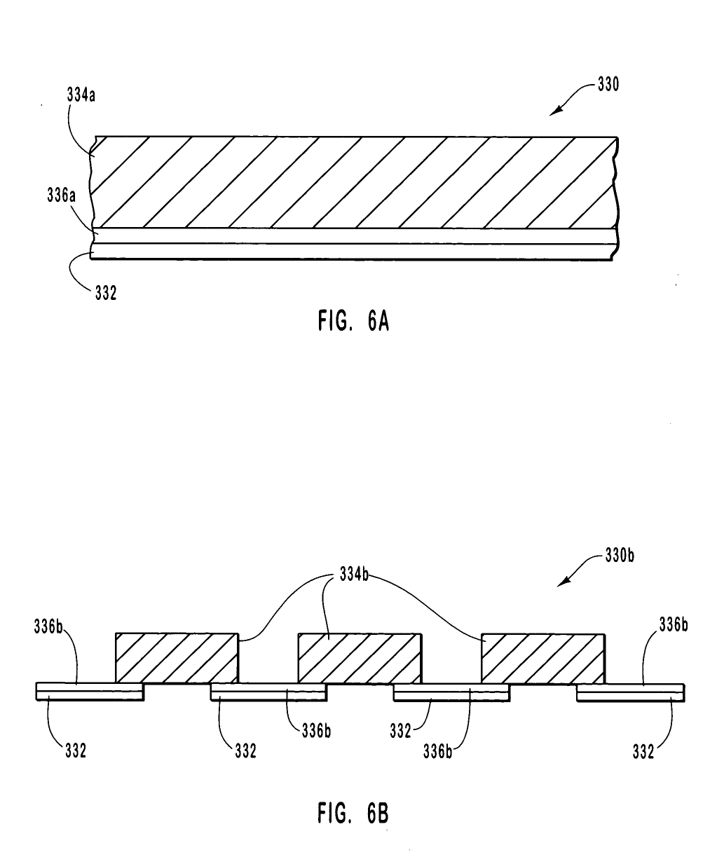

Referring to FIGS. 6A and 6B illustrated are two exemplary configurations of web 330. As shown in FIG. 6A, web 330 includes a substrate 334a that supports an interface layer 336a and target material 332. The substrate 334a provides structural support to web 330. The substrate 334a, therefore, can include, but are not limited to, metals, alloys, synthetic materials, natural materials, polymers, plastics, combinations thereof, or other materials that can resist the temperatures associated with the PLD process or be transparent to the wavelength of electromagnetic radiation generated by laser source 202 (FIG. 2). It can be understood that web 330 can only include interface layer 336a and target material 332 when interface layer 336a provides sufficient strength and flexibility to function or act as substrate 334a. In still another configuration, when interface layer 336a has sufficient strength and flexibility to support target material 332, web 330 can include a removable substrate 334a, such that substrate 334a is removed from contact with interface layer 336 before ablation during the deposition process.

The interface layer 336a provides a surface for depositing target material 332 and prevents contamination of target material 332 from contact with substrate 334a. Various materials can form interface layer 336a, so long as the material is transparent to the electromagnetic radiation generated by laser source 202 (FIG. 2) and, if possible, benign to the function of target material 332 should any portion of interface layer 336a be ablated with target material 332. When substrate 334a is transparent to the wavelength of electromagnetic radiation generated by laser source 202 (FIG. 2), the material forming interface layer 336a can be chosen based upon whether or not interface layer 336a adheres to substrate 334a and to target material 332.

With respect to the benign characteristics of interface layer 336a, an example is provided to illustrate. This example is provided only for aid of explanation and is not limiting to the types of material that can be used for interface layer 336a. In the event that one is depositing Titanium (Ti) then target material 332 of Ti can sit on interface layer 336a formed from Titanium Dioxide (TiO₂). In such a case, there will be some oxidation of the Ti on the surface, so slight contamination with the TiO₂ of interface layer 336a does not affect the deposited target material.

Referring now to FIG. 6B, illustrated is another exemplary embodiment of the web, indicated with numeral 330b. Web 330b includes a matrix substrate 334b upon which is deposited interface layer 336b. As with web 330, target material 332 is deposited upon interface layer 336b. With substrate 334b having a matrix configuration, the flexibility of substrate 334b is increased over webs having a continuous substrate. Further, substrate 334b can be fabricated from materials that are not transparent to the particular wavelength of electromagnetic radiation generated by laser source 202 (FIG. 2), since the laser beam can pass through the holes or spaces formed in the matrix and be incident upon the interface layer 336b and hence target material 332. By so doing, substrate 334b eliminates the possibility of vaporized substrate contaminating other portions of substrate 334b, interface layer 336b, or target material 332. In this configuration, interface layer 336b can be stiff or more inflexible than substrate 334b to provide sufficient support for the deposited target material 332.

Techniques for applying interface layer 336a or 336b and target material 332 to substrate 334a or substrate 334b are known in the art and are used to make rolls of metallic materials, such as aluminized plastics. These techniques can be used to create web 330 of the present invention. For example, silicon can be deposited onto one side of web 330 if cassette 300 is later to be used to deposit silicon on a substrate. The web 330 can have a relatively high melting point so as not to melt and contaminate target material 332 in the PLD process. Alternatively, web 330 can be at least partially transparent to the wavelength of electromagnetic radiation generated by laser source 202 (FIG. 2). For example, web 330 can have a similar configuration to web 230 (FIG. 2), such as, but not limited to, a mesh, matrix, or solid piece of material.

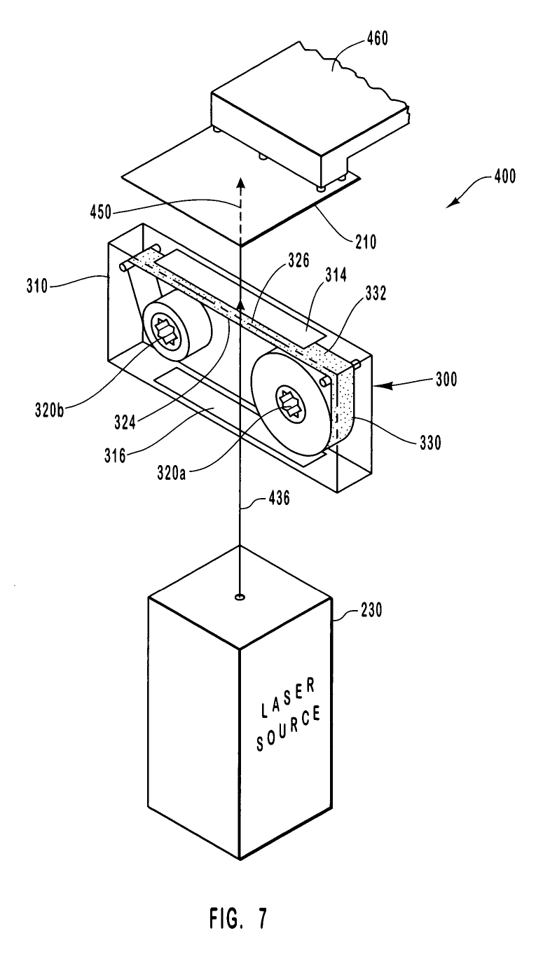

FIG. 7 illustrates a schematic view of an improved pulsed laser deposition system incorporating the cassette of FIG. 5. The system 400 utilizes laser source 230 to deposit target material 332 carried by cassette 300 onto a substrate 210. The laser source 230, substrate 210, and cassette 300 are similar in design and construction to like components shown in FIG. 2-6. One skilled in the art will realize that other structures besides the cassette shown can be used without departing from the spirit or scope of the present invention.

As illustrated, a moveable mechanism 460 carries substrate 210. Movable mechanism 460 is adapted to move substrate 210 during the PLD process so that precise deposition of target material 332 upon substrate 210 in the desired pattern occurs. Generally, movable mechanism 460 allows substrate 210 to be precisely moved in a two or three-dimensional space in relation to the other components. This movable mechanism 460 can include known electrical devices, mechanical devices, electromechanical devices, magnetic devices, hydraulic devices, pneumatic devices, or combinations thereof suitable for moving an object to an exact position.

In another configuration, laser source 230 can be movable, while substrate 210 is maintained in a fixed position. By so doing, laser source 230 can move to a particular area to deposit target material 332 onto substrate 210. It is contemplated that laser source 230, web 330, and substrate 210 can all be moved simultaneously or independently to effect the deposition of target material 332 onto substrate 210. Hence, one or more of laser source 230, web 330, and substrate 210 can be moved by one or more electrical devices, mechanical devices, electromechanical devices, magnetic devices, hydraulic devices, pneumatic devices, or combinations thereof.

The operation of the PLD process using system 400 is similar to the operation described in FIG. 2-4, except that the target material is incorporated into cassette 300. The cassette 300 allows for a user or machine (not shown) to advance web 330 within cassette 300 to expose a fresh section of target material 332 to be deposited onto substrate 210. The laser source 430 emits a laser beam 436 into the back or under side of web 330 within cassette 300. As previously discussed, laser beam 436 can pass through web 330 without heating or destroying web 330 to be incident upon target material 332 deposited thereupon. Alternatively, laser beam 436 can vaporize the substrate of web 330, since the vaporized material forming the substrate remains within cassette 300 and will not contaminate the substrate or target material 332. In the event that the vaporized substrate has the potential for contaminating the remaining substrate and/or target material 332, use of web 330b illustrated in FIG. 5B eliminates the need to vaporize the substrate by providing direct access to the interface layer and hence target material 332 for laser beam 436.

Beam 436 strikes a side 324 of target material 332. The beam 436 pulse duration, width, and power can all be modulated to effectively heat target material 332 without completely penetrating to a side 326 of target material 332. The target material 332 is heated up and vaporized or ablated in a similar manner to that described in reference to FIGS. 2-4. The vaporized target material 450 is then transmitted to substrate 210. Moveable mechanism 460 precisely positions substrate 210 to achieve the desired location and thickness of thin film deposition. Multiple passes can be required to achieve a thin film deposition of desired thickness.

Although discussion is made herein to use of the processes and techniques with performing PLD, the processes and techniques described herein are well suited to pulsed laser chemical vapor deposition (PL-CVD). For PL-CVD, a significant part of the deposition process involves chemical reactions taking place on or near the surface of the substrate. Through the processes and techniques described herein, it is understood that by using multiple beams at different wavelengths the delivery of the material (the ablation process), and the reactions on or near the substrate can be controlled independently in the PL-CVD process.

The present invention can be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A system for deposition of a material onto a substrate, the system comprising:
a laser source configured to emit a laser beam;
a target positioned so said laser beam is incident upon a first surface of said target; and
a substrate positioned so that said target is disposed between said laser source and said substrate, said substrate receiving a vaporized portion of said target from another surface of said target upon said laser beam striking said target.

2. The system as recited in claim 1, wherein said target comprises a web and a target material deposited upon said web.

3. The system as recited in claim 1, wherein said another surface is in close proximity to said substrate.

4. The system as recited in claim 1, wherein said vaporized portion of said target is ejected from said another surface of said target opposite to said first surface.

5. The system as recited in claim 1, wherein said substrate is in contact with said another surface of said target.

6. The system as recited in claim 1, wherein said substrate is separated from said target by a distance of less than about 1 mm.

7. A system for deposition of a material onto a substrate, the system comprising:
a laser source configured to emit a laser beam;
a target comprising a first surface and a second surface disposed from said first surface, said first surface being positioned so as to be struck by said laser beam; and
a substrate positioned in close proximity to said second surface of said target so that said target is at least disposed between said laser source and said substrate, upon said target being struck by said laser beam, said substrate receives a vaporized portion of said target from said second surface of said target.

8. The system as recited in claim 7, wherein upon being incident upon said substrate, said vaporized portion of said target has a diameter smaller than a diameter of said laser beam.

9. The system as recited in claim 7, wherein said substrate is at least partially transparent to said laser beam.

10. The system as recited in claim 7, wherein said target comprises a web and a target material coupled to said web.

11. The system as recited in claim 10, wherein said web is at least partially transparent to said laser beam.

12. The system as recited in claim 1, further comprising a cassette adapted to carry said target.

13. The system as recited in claim 12, wherein said cassette comprises:
a web having a target material;
a pair of reels carrying said web; and
a housing supporting said target and said pair of reels.

14. The system as recited in claim 13, wherein said web extends from a first reel of said pair of reels to a second reel of said pair of reels.

15. The system as recited in claim 13, wherein said substrate is positioned less than 1 mm from said target material.

16. The system as recited in claim 13, wherein said housing further comprises at least one window through which said laser beam passes.

17. A method for depositing a target material onto a substrate, the method comprising:
a step for directing a laser beam to a target comprising a target material; and
a step for ablating a portion of said target material through said target under the influence of said laser beam, wherein ablating said portion of said target material vaporizes said portion and directs said portion onto the substrate.

18. A method as recited in claim 17, further comprising a step for moving said target relative to the substrate.

19. A method as recited in claim 17, further comprising a step for creating a melting zone in said target, said melting zone propagating through said target.

20. A method as recited in claim 17, further comprising a step for creating an aperture in said target, said portion of said target material ejecting from said aperture toward the substrate.

21. A method as recited in claim 17, wherein said step for ablating comprises ablating a portion of said target so that a diameter of said portion incident upon said substrate is smaller than a diameter of said laser beam.

22. A method for depositing a target material onto a substrate, the method comprising:
a step for directing a laser beam to a target comprising a web and a target material deposited upon said web; and
a step for ablating a portion of said target material through said web under the influence of said laser beam, wherein ablating said portion of said target material vaporizes said portion and directs said portion onto the substrate.

23. The method of claim 22, wherein said laser beam is a pulsed ultraviolet laser beam originating from a laser source.

24. The method of claim 23, further comprising a step for creating a melting zone in said target material, said melting zone propagating through said target material.

25. The method of claim 22, further comprising a step for positioning the substrate to within 1 mm of said target material.

26. The method of claim 22, further comprising a step for moving the substrate relative to said target material.

27. The method of claim 22, further comprising a step for moving the target material relative to the substrate.

28. The method of claim 27, wherein said step for moving said target material relative to the substrate comprises a step for moving said target material from a first reel of a cassette to a second reel of said cassette, said cassette comprising a housing supporting said first reel and said second reel.
